(19) United States
(12) Patent Application Publication
(10) Pub. No.: US 2024/0284759 A1
(43) Pub. Date: Aug. 22, 2024

(54) Display Panel, Preparation Method and Display Apparatus

(71) Applicant: HKC CORPORATION LIMITED, Shenzhen (CN)

(72) Inventors: Lei JIANG, Shenzhen (CN); Yangchuan ZHOU, Shenzhen (CN); Rongrong LI, Shenzhen (CN)

(73) Assignee: HKC CORPORATION LIMITED, Shenzhen (CN)

(21) Appl. No.: 18/434,831

(22) Filed: Feb. 7, 2024

(30) Foreign Application Priority Data
Feb. 21, 2023 (CN) 202310144365.0

(51) Int. Cl. H10K 59/80; C23C 16/50; C23C 16/56; G03F 7/00; H10K 59/35

(52) U.S. Cl. CPC H10K 59/873; C23C 16/50; C23C 16/56; G03F 7/0005; G03F 7/0035; H10K 59/35

(57) ABSTRACT

The present application relates to the technical field of display, and provides a display panel, a preparation method and a display apparatus, wherein the display panel includes a display substrate and an encapsulation layer: each display pixel in the display substrate includes a plurality of subpixel regions; the encapsulation layer is located on a light outlet side of the display substrate, and the encapsulation layer includes a first inorganic layer and an organic layer which are arranged successively in a direction away from the display substrate; the first inorganic layer includes light transmitting regions and thickening regions, each light transmitting region correspondingly covers at least one subpixel region in an orthographic direction on the display substrate; and a thickness of the thickening regions is greater than the thickness of the light transmitting regions.

### CROSS REFERENCE TO RELATED APPLICATIONS

The present application claims the priority of Chinese patent application No. 202310144365.0 entitled “Display Panel, Preparation Method and Display Apparatus” and filed on Feb. 21, 2023, of which the entire contents are incorporated herein by reference.

### TECHNICAL FIELD

The present application relates to the technical field of display, in particular to a display panel, a preparation method and a display apparatus.

### BACKGROUND

Organic electroluminescent display apparatuses, such as organic light-emitting diode (OLED) displays, have the characteristics required for new technological directions, such as automatic luminescence, a wide viewing angle, fast response, a small thickness and high contrast. Therefore, as a next generation of flat panel display apparatuses, organic electroluminescent apparatuses have been widely used in smart phones, tablets and even computer display panels.

At present, in the display panel industry, the most challenging and avant-garde technology is a flexible display panel, that is, an existing OLED display panel is made into a flexible and foldable display, which has the characteristics of a smaller thickness and a low weight, and can be assembled on any luminous display, such as flexible mobile phones, computers, tablets and other personal portable devices.

In a manufacture procedure of a flexible/foldable display panel, a TFE (thin-film encapsulation) process is used to encapsulate a display substrate, so that the panel can still have a function of flexible bending on the basis of display. At present, thin-film encapsulation generally adopts a 3-layer structure, that is, inorganic layer-organic layer-inorganic layer, wherein the inorganic layers are generally deposited in a mode of plasma enhanced vapor deposition (PECVD), and the organic layer as a middle layer is generally realized in a mode of inkjet printing.

However, since a thickness of a first layer, that is the first inorganic layer, of a thin-film encapsulation structure, which plays a key role in the encapsulation, can not be too large (because a large thickness leads to decrease in light output efficiency, resulting in loss of display brightness), once the substrate that has gone through the OLED manufacture procedure has abnormal particles, if the first layer of the thin-film encapsulation structure can not cover the abnormal particles well, the first layer of the thin-film encapsulation structure is prone to local fractures and cracks.

However, the next manufacture procedure is the deposition of the second layer of the thin-film encapsulation structure, that is, the organic material layer. Because the organic material has a small amount of water, the water in the layer will enter an OLED effective display region through the local fracture or local crack of the first layer of the thin-film encapsulation structure, it will lead to sharp shortening of the service life of a cathode and luminous materials under the first layer of the thin-film encapsulation structure, local display brightness drops, and as a result, black spots appear in the display panel.

### SUMMARY

The present application aims to provide a display panel, a preparation method and a display apparatus, which can effectively solve the problem of poor encapsulation of the display panel.

In a first aspect, an embodiment of the present application provides a display panel, including a display substrate and an encapsulation layer, each display pixel in the display substrate includes a plurality of subpixel regions, and the encapsulation layer is located on a light outlet side of the display substrate, and includes a first inorganic layer, an organic layer and a second inorganic layer which are successively arranged in a direction away from the display substrate, wherein the first inorganic layer includes light transmitting regions and thickening regions, each light transmitting region correspondingly covers at least one subpixel region in an orthographic direction on the display substrate, and a thickness of each thickening region is greater than that of the light transmitting region.

In a second aspect, an embodiment of the present application provides a preparation method of a display panel, including steps: forming a first inorganic layer on a light outlet side of a display substrate, wherein each display pixel in the display substrate includes a plurality of subpixel regions; forming a photoresist layer on a side of the first inorganic layer away from the display substrate; performing exposure and development on the photoresist layer corresponding to a plurality of light transmitting regions on the first inorganic layer, to expose the plurality of light transmitting regions on the first inorganic layer, each light transmitting region correspondingly covering at least one subpixel region in an orthographic direction on the display substrate; and etching each light transmitting region on the first inorganic layer, to etch each light transmitting region to a preset thickness, and forming thickening regions between the adjacent light transmitting regions.

In a third aspect, an embodiment of the present application provides a display apparatus, including the above display panel or including the display panel prepared through the above preparation method.

According to the display panel, the preparation method and the display apparatus provided by the embodiments of the present application, since the first inorganic layer includes the light transmitting regions and the thickening regions, each light transmitting region correspondingly covers at least one subpixel region in the orthographic projection direction on the display substrate; and the thickness of the thickening regions is greater than that of the light transmitting regions. The covering ability of foreign bodies is enhanced by locally adding the thin-film encapsulation first inorganic layer, so that the foreign bodies can be effectively covered even if there are foreign bodies. At the same time, the light transmitting regions corresponding to the subpixel regions do not have the problem of thickening, or it is considered that it can be thinned as much as possible, because the display light transmission will not be affected, so as to solve the problem of poor encapsulation and improve the yield. At the same time, because the film thickness of the light transmitting regions is not increased, the luminous efficiency will not be affected.

### BRIEF DESCRIPTION OF FIGURES

Features, advantages, and technical effects of exemplary embodiments of the present application are described below with reference to accompanying drawings. In the accompanying drawings, the same parts are marked with the same reference signs. The accompanying drawings are not drawn according to the actual scale, but are only used to indicate the relative position relationship. A layer thickness of some parts adopts an exaggerated plotting mode so as to facilitate understanding. The layer thickness in the accompanying drawing does not represent the proportional relationship of the actual layer thickness.

FIG. 1 shows a first schematic diagram of a sectional structure of a display panel of a first embodiment.

FIG. 2 shows a second schematic diagram of a sectional structure of a display panel of a first embodiment.

FIG. 3 shows a schematic diagram of a local sectional structure of a position A of FIG. 2.

FIG. 4 shows a schematic diagram of a sectional structure of a display panel of a second embodiment.

FIG. 5 shows a flowchart of a preparation method of a display panel of a second embodiment.

FIG. 6 shows a schematic structural diagram of a step 1 of a preparation method of a display panel of a second embodiment.

FIG. 7 shows a schematic structural diagram of a step 2 of a preparation method of a display panel of a second embodiment.

FIG. 8 shows a schematic structural diagram of step 3 of a preparation method of a display panel of a second embodiment.

FIG. 9 shows a schematic structural diagram of a step 4 of a preparation method of a display panel of a second embodiment.

FIG. 10 shows a schematic structural diagram of a step 5 of a preparation method of a display panel of a second embodiment.

FIG. 11 shows a schematic structural diagram of a step 6 of a preparation method of a display panel of a second embodiment.

FIG. 12 shows a schematic structural diagram of a step 7 of a preparation method of a display panel of a second embodiment.

FIG. 13 shows a schematic structural diagram of a step 8 of a preparation method of a display panel of a second embodiment.

FIG. 14 shows a schematic structural diagram of a step 9 of a preparation method of a display panel of a second embodiment.

### REFERENCE SIGNS ARE ILLUSTRATED AS FOLLOWS

1, base substrate; 2, luminous structure layer; 21, first subpixel region; 22, second subpixel region; 23, third subpixel region; 3, encapsulation layer; 31, first inorganic layer; 32, organic layer; and 33, second inorganic layer.

### DETAILED DESCRIPTION

Features and exemplary embodiments of each aspect of the present application are described in detail below. In the detailed description below, many specific details are presented so as to provide comprehensive understanding of the present application. However, it is obvious to those skilled in the art that the present application may be implemented without the need for some of these specific details. The description of embodiments below is only intended to provide better understanding of the present application by showing examples of the present application. At least part of publicly known structures and techniques are not shown in the accompanying drawings and descriptions below in order to avoid unnecessary ambiguity in the present application; and moreover, for clarity, the size of a regional structure may be exaggerated. In addition, the features, structures or properties described below may be combined in one or more embodiments in any suitable mode.

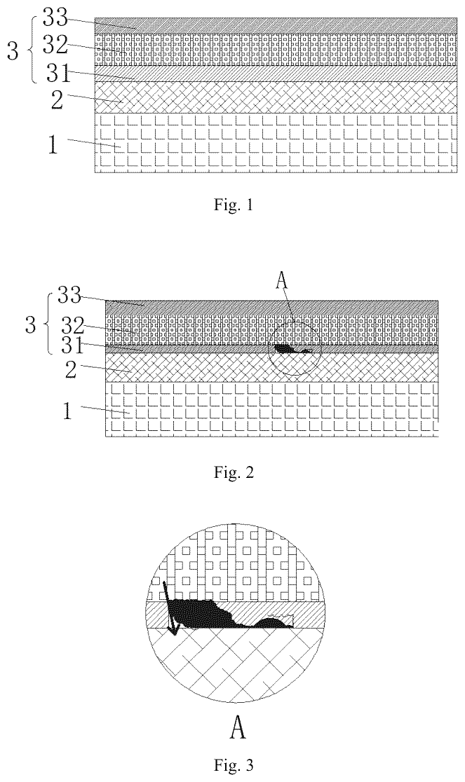

FIG. 1 shows a first schematic diagram of a sectional structure of a display panel of a first embodiment, FIG. 2 shows a second schematic diagram of a sectional structure of a display panel of a first embodiment, and FIG. 3 shows a schematic diagram of a local sectional structure of a position A of FIG. 2; and a display substrate in the first embodiment mainly includes a base substrate 1, a luminous structure layer 2 and a thin-film encapsulation layer 3, and the thin-film encapsulation layer 3 mainly includes a first inorganic layer 31, an organic layer 32 and a second inorganic layer 33. A function of the first inorganic layer 31 is to block water oxygen in the organic layer 32, a function of the organic layer 32 is to buffer stress of the first inorganic layer, and a function of the thin-film encapsulation second inorganic layer 33 is to block external water oxygen.

Since a thickness of a first layer, that is the first inorganic layer 31, of the thin-film encapsulation structure, which plays a key role in the encapsulation, cannot be too large (because a large thickness leads to decrease in light output efficiency, resulting in loss of display brightness), once the display substrate that has gone through an OLED manufacture procedure has abnormal particles, as shown in FIG. 3, the first inorganic layer 31 of the thin-film encapsulation structure cannot cover the abnormal particles well, the first inorganic layer 31 of the thin-film encapsulation structure will be locally fractured, or it is considered that there will be cracks.

However, the next manufacture process is the thin-film encapsulation second layer, that is, the preparation of the organic layer 32, which is formed by the deposition of an organic material layer. Because an organic material of the organic layer 32 has a small amount of water, the water in the layer will enter an OLED effective display region through the local crack of the first inorganic layer 31. The service life of a cathode and luminescent materials under the first inorganic layer 31 is shortened sharply, and the local display brightness decreases, resulting in black spots in the display panel.

As shown in FIG. 3, impurity gas such as water vapor in the organic layer 32 will enter an OLED film layer along an arrow path, affecting the service life of each component of a local OLED. As organic foreign matter is unavoidable and a certain amount of organic foreign matter exists, the production yield will decrease and the production cost will increase.

The main purpose of embodiments of the present application is to enhance the covering ability of the foreign body by enhancing the thin-film encapsulation first inorganic layer, and moreover, light transmitting regions are not thickened while the thin-film encapsulation first inorganic layer is enhanced, so as to solve the technical problem of poor encapsulation of the display panel. In order to facilitate more intuitive understanding of the present application, the present application is illustrated schematically below in combination with the accompanying drawings:

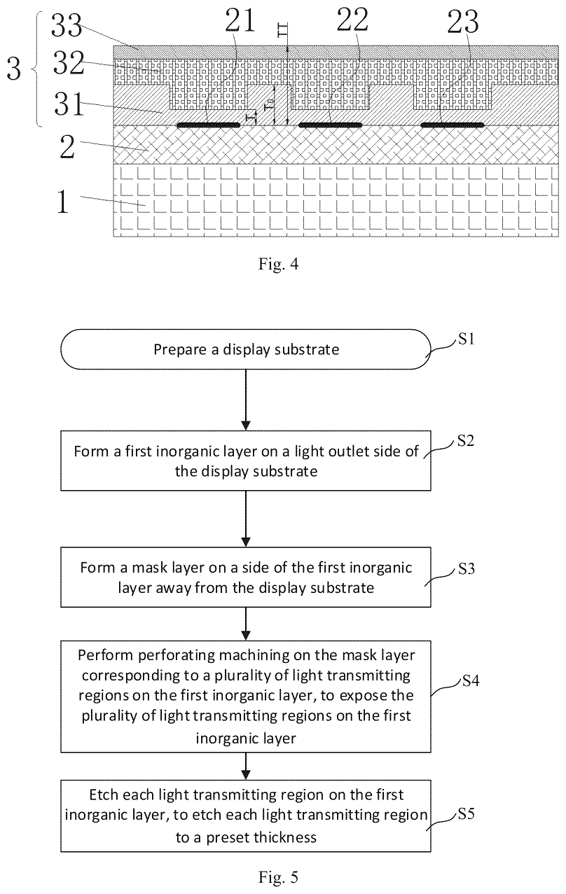

FIG. 4 shows a schematic diagram of a sectional structure of a display panel of a second embodiment, as shown in the figure, the second embodiment of the present application provides the display panel, the display panel mainly includes a luminous structure layer 2 and an encapsulation layer 3: the luminous structure layer 2 is an OLED display substrate herein, and an OLED luminous layer can be formed on a flexible substrate 1. Each display pixel in the luminous layer in the luminous structure layer 2 includes a plurality of subpixel regions, and each display pixel includes a first subpixel region 21, a second subpixel region 22 and a third subpixel region 23. The encapsulation layer 3 is located on a light outlet side of the luminous structure layer 2, and the encapsulation layer 3 includes a first inorganic layer 31, an organic layer 32 and a second inorganic layer 33 which are arranged successively in a direction away from the luminous structure layer 2. The first inorganic layer 31 includes light transmitting regions and thickening regions, each light transmitting region correspondingly covers at least one subpixel region in an orthographic direction on the display substrate, and a thickness of each thickening region is greater than that of the light transmitting region. Accordingly, in the case of ensuring that the inorganic film thickness of a display pixel region does not change, the overall encapsulation strength of the panel is increased, stronger encapsulation ability on the display panel is achieved, and reliability performance is higher.

At the same time, the thickness of the light transmitting regions can be reduced as much as possible, in the present embodiment, a non-light-transmitting region of the first inorganic layer 31 is thickened, which plays a role in coating (as for why the abnormal particles on the PDL between the pixels is caused by contact friction between a mask plate used in the manufacture procedure of evaporating an OLED and the substrate, the contact must be in a highly protruding place of the panel, and a PDL between pixels is a region with a large height) abnormal particles between the pixels (located on a pixel definition layer, called the PDL for short). Only when the coating effect is better can the intrusion of water oxygen above the first inorganic layer 31 be avoided. The first inorganic layer on the luminous region is thinned so as not to affect the luminous efficiency, because the inorganic layer deposition is uniform, the thickness of all parts of the panel is consistent, the thickness of the first inorganic layer 31 on the PDL between the pixels increases, and the thickness of the first inorganic layer on the luminous region will also increase. However, in the embodiment of the present application, no additional steps are required to realize the preparation of this structure, only the manufacture procedure time on the deposition of the first inorganic layer 31 is prolonged.

One of the purposes of the second organic layer 32 here is for flattening, in the actual process, because a molding method is a mode of printing, its upper surface is not only a contact surface with the second inorganic layer 33 and is also flat, and its thickness is not increased. However, an advantage of the present embodiment is that when the first inorganic layer 31 forms a continuous concave and convex shape, it is conducive to the formation of a thick and thin alternate shape of the organic layer 32, which is more conducive to buffer of bending stress when the display panel is bent, and will not lead to the uneven contact surface between the second layer, namely the organic layer and the second inorganic layer. At the same time, it can also reduce the use of organic layers and reduce production costs.

As shown in FIG. 4, the first inorganic layer 31 in the present embodiment will form a square wave shape (or zigzag shape, or wall shape) from the section, so that thickening and strengthening regions (that is, the thickening regions) can be formed in the non-light-transmitting region, so that a plurality of spaced gaps or slot shapes called spaces can be formed on the light outlet side of the first inorganic layer 31. The organic layer 32 formed on its outer surface will form a thick and thin alternate shape, which is more conducive to buffer of the bending stress when the display panel is bent, and will not lead to the uneven contact surface between the second layer, namely the organic layer and the second inorganic layer.

In a possible implementation, the thickness of the thickening regions in the first inorganic layer 31 is at least 1.2 times the thickness of the light transmitting regions, and the thickness of the thickening regions is within 3 times the thickness of the light transmitting regions. In a possible implementation, the overall thickness of the encapsulation layer 3 is less than or equal to 20 μm, and the overall thickness of the encapsulation layer 3 is equal to or greater than the thickness of the first inorganic layer 31. The first inorganic layer 31 plays a key role in the encapsulation yield, and the thickness T of the light transmitting regions generally ranges from 0.5 μm to 1.5 μm to avoid the light penetration loss caused by the thickness increase, but the height of foreign bodies generated in the actual production process may be greater than this thickness, and as a result, the inorganic film layer cannot cover the foreign bodies. The embodiment of the present disclosure increases the thickness TO of each thickening region of the first inorganic layer 31, and the thickness is generally required to be: T<T0<(2˜3)*T. The reason why the thickness is not infinite is mainly because the larger the thickness is, the longer the manufacture procedure time is, the more inorganic raw materials are consumed, and the more the cost increases. The overall thickness TT remains at an existing benchmark, and can be even smaller, with a range of T≤TT≤20 μm. The thickness of the light transmitting regions ranges from 0.5 μm to 1.5 μm.

In the embodiment of the present application, the width of each light transmitting region is greater than the width of the corresponding subpixel region in the orthographic projection direction of the light transmitting region. In order to ensure that the light output of the luminous pixel region is not affected at all, the thinning width of the light transmitting regions can be greater than the width of the pixel region, which may be L<W≤L+5 μm in the example (refer to the mark in FIG. 10).

In a possible embodiment, each display pixel includes the first subpixel region 21, the second subpixel region 22, and the third subpixel region 23, and correspondingly, each light transmitting region of the first inorganic layer 31 includes the first light transmitting region, the second light transmitting region, and the third light transmitting region; the first light transmitting region correspondingly covers the first subpixel region in the orthographic direction, the second light transmitting region correspondingly covers the second subpixel region in the orthographic direction, and the third light transmitting region correspondingly covers the third subpixel region in the orthographic direction; and the thickness of the first light transmitting region is the first thickness, the thickness of the second light transmitting region is the second thickness, and the thickness of the third light transmitting region is the third thickness. It should be noted here that luminous subpixels of the panel are generally divided into three types, namely R, G, and B, and the figure shows and does not specifically represent R, G, and B, that is, the thickness of the light transmitting regions, corresponding to the luminous regions representing R, G, and B, of the first inorganic layer 31 is the same after thinning. At the same time, in order to improve the luminous efficiency of different luminous pixels, the thinning thickness of the luminous regions of R, G and B pixels can be made inconsistent, that is, the luminous region of the R pixel is the first thickness Tr, the luminous region of the G pixel is the second thickness Tg, and the luminous region of the B pixel is the third thickness Tb.

The first thickness Tr, the second thickness Tg and the third thickness Tb are different; in this way, it facilitates adaptation of matching light transmittance according to the difference of luminous brightness of each subpixel, so that the light outlet brightness of the subpixels of different colors on the light outlet side is better in line with the display demand. Or in another embodiment, two of the first thickness Tr, the second thickness Tg, and the third thickness Tb have the same thickness but are not the same thickness as the rest, so as to facilitate the adaptation of the matching light transmittance according to the difference in luminous brightness between one subpixel and the other two subpixels, and thus, the brightness of the subpixels of the different colors on the light outlet side is better in line with the display demand.

In the embodiment of the present application, the first inorganic layer 31 is used to enhance the encapsulation effect, and the water resistance mainly depends on the first inorganic layer 31, while the organic layer 32 is a film layer for flattening and stress buffering, which generally has no water resistance effect, but the organic layer requires a certain fluidity, which contains a small amount of liquid, and is risky for the film encapsulation. This means that the organic layer 32 and the second inorganic layer 33 may not be used, saving an organic layer material and a second inorganic layer material, as well as a manufacture procedure device and production cost. Alternatively, in another embodiment, the overall thickness of the organic layer 32 may also be made small enough to be used only to flatten the light outlet side of the first inorganic layer 31.

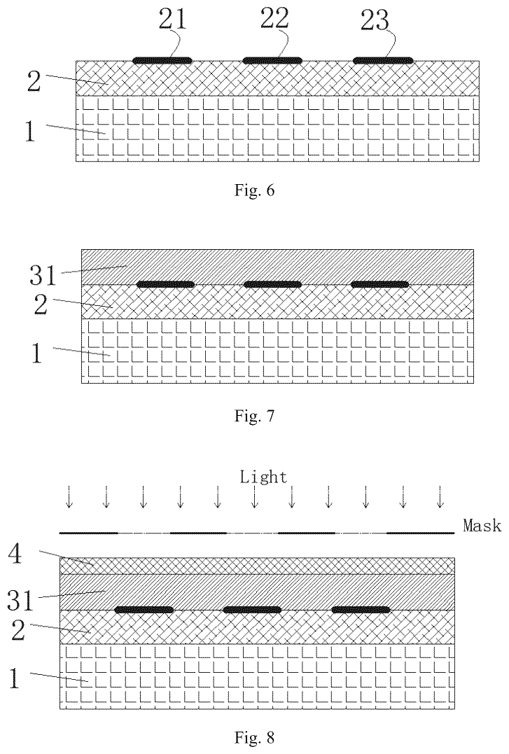

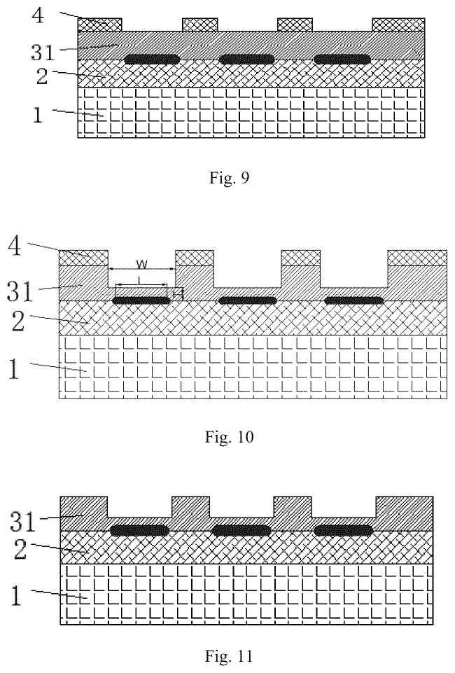

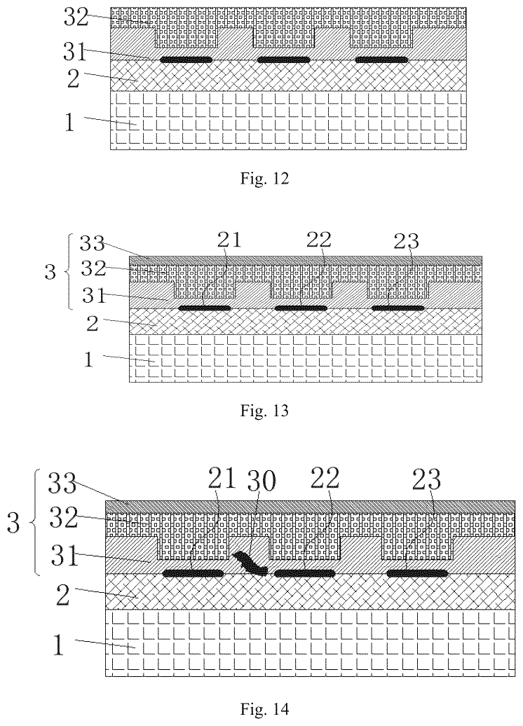

In a second aspect, an embodiment of the present application proposes a preparation method of a display panel, including the following steps:
S1, a display substrate shown in FIG. 6 is prepared, wherein in the present embodiment, the display substrate is a substrate that completes an OLED luminous stack structure.
S2, a first inorganic layer 31 is formed on a light outlet side of a luminous structure layer 2; deposition of the thin-film encapsulation first inorganic layer 31 is performed on the substrate that completes the OLED luminous stack structure, as shown in FIG. 7, wherein a thickness of the first inorganic layer 31 is T<TO<(2˜3)T, 0.5 μm<T<1.5 μm, a manufacture procedure method may be a PECVD method, and a material of the first inorganic layer 31 may be SiOx, SiNx, SiNOx or a ceramic material.
S3, a photoresist layer 4 is formed on a side of the first inorganic layer 31 away from the luminous structure layer 2, wherein as shown in FIG. 8, the photoresist layer 4 is formed through deposition of an organic layer on the encapsulation first inorganic layer, that is, photo resin (called PR for short), with a thickness ranging from 2 μm to 4 μm, which can be coated in a mode of coating and a material can be selected as a polyimide material.
S4, exposure and development are performed on the photoresist layer 4 corresponding to a plurality of light transmitting regions on the first inorganic layer 31, to expose the plurality of light transmitting regions on the first inorganic layer 31, wherein the “perforating” refers to the exposure and development of the organic layer, that is, the photo resin (PR), in accordance with a luminous pattern, the pattern is all luminous subpixel regions, that is, a position above the luminous subpixel regions is light-transmitting, and a position above the remaining non-luminous region is not light-transmitting, or the position above the luminous subpixel regions is not light-transmitting, and the position above the remaining non-luminous region is light-transmitting. As shown in FIG. 8, the purpose is to expose the PR above the luminous subpixel regions, there is no change in the PR of the non-luminous regions, the PR of the exposed organic layer is developed, so that the PR on the luminous subpixel regions is removed, because in the previous step, the PR of the luminous subpixel regions has been modified, and under the action of a special liquid medicine, the modified PR is reacted and removed, while the unmodified PR cannot react and be removed, as shown in FIG. 9.
S5, the light-transmitting regions on the first inorganic layer 31 are etched, to etch the light-transmitting regions to a preset thickness, and thickening regions are formed between the adjacent light-transmitting regions. A region where the PR of the organic layer is removed, and the encapsulation first inorganic layer is exposed is etched, so that the thickness of the encapsulation first inorganic layer is reduced to a preset thickness, as shown in FIG. 10, the thickness of the thinned inorganic film layer is 0.5 μm≤T≤1.5 μm, in order to ensure that light outlet of luminous subpixels is not affected at all, the thinning width may be greater than the width of the subpixels, and may be L<W≤L+5 μm, it should be noted here that luminous subpixels of the panel are divided into three types, namely R, G, and B, and the figure shows and does not specifically represent R, G, and B, that is, the thickness of the light transmitting regions, corresponding to the luminous regions representing R, G, and B, of the first inorganic film layer is the same after thinning. At the same time, in order to improve the luminous efficiency of different luminous pixels, the thinning thickness of the luminous regions of R, G and B pixels can be made inconsistent, that is, the luminous region of the R pixel is the first thickness Tr, the luminous region of the G pixel is the second thickness Tg, the luminous region of the B pixel is the third thickness Tb, the thickness of the three is different, or the thickness of the two may be the same. The PR of the developed organic layer is completely removed, as shown in FIG. 11, and the step removes a non-normal-encapsulation film layer, to obtain a designed first inorganic layer 31.
S6, manufacturing of a thin-film encapsulation second organic layer is performed in combination with an encapsulation strength condition in an ink-jet printing mode, as shown in FIG. 12.
S7, a third layer is encapsulated, that is, deposition of the second inorganic layer 33 is performed, wherein as shown in FIG. 13, a thickness is the same as that of the first inorganic layer 31 and may also be lower than that of the first inorganic layer 31, and a manufacturing mode may adopt a PECVD mode.

In a third aspect, an embodiment of the present application presents a display apparatus including the display panel as described above, or the display panel prepared by the preparation method as described above.

As shown in FIG. 14, according to the display panel, the preparation method and the display apparatus provided according to the embodiments of the present application, since the first inorganic layer 31 includes the light transmitting regions and the thickening regions, and each light transmitting region correspondingly covers at least one subpixel region in the orthographic projection direction on the luminous structure layer 2; and the thickness of the thickening regions is greater than that of the light transmitting regions. The covering ability of foreign bodies 30 is enhanced by locally increasing the thin-film encapsulation first inorganic layer 31, so that the foreign bodies 30 can be effectively covered even if there are foreign bodies 30, so as to solve the problem of poor encapsulation, and improve the yield, and because the film thickness of the light transmitting regions does not increase, it will not affect the luminous efficiency.

It should be easy to understand that the words “on”, “above” and “onto” should be interpreted in the broadest possible way, so that “on” means not only “directly on something”, but also “on something” with intermediate features or layers in between, and “above” or “onto” includes not only the meaning of “above something” or “onto”, but can also include the meaning of “above something” or “onto” without intermediate features or layers in between (i.e. directly on something).

The term “base substrate” as used herein refers to a material on which a subsequent material layer is added. The base substrate itself can be patterned. The material added to the top of the base substrate can be patterned, or can remain unpatterned. In addition, the base substrate may include a series of materials within a wide range, such as silicon, germanium, gallium arsenide and indium phosphide. Alternatively, the base substrate can be made of a non-conductive material (e.g., glass, plastic, or sapphire wafer).

The term “layer” as used herein may refer to a part of a material that includes a region with a certain thickness. The layer may extend over an entire underlying or overlying structure, or may have a smaller extent than the extent of the underlying or overlying structure. In addition, the layer may be a region of a homogeneous or non-homogeneous continuous structure whose thickness is less than the thickness of the continuous structure. For example, the layer may be located between a top surface and a bottom surface of the continuous structure or between any pair of transverse planes at the top surface and bottom surface. The layers may extend laterally, vertically, and/or along a conical surface. The base substrate may be the layer, may include one or more layers in it, and/or may have one or more layers located on, above and/or below it. The layer can include a plurality of layers. For example, an interconnect layer may include one or more conductors and contact layers (within which contacts, interconnection lines and/or through-holes are formed), and one or more dielectric layers.

Finally, it should be noted that the above embodiments are used only to illustrate the technical solution of the present application, and not to restrict it; although the present application is described in detail with reference to the embodiments, those of ordinary skill in the art should understand that they may modify the technical solution recorded in the above embodiments, or make equivalent substitutions for some or all of the technical features thereof; and such modification or replacement shall not make the essence of the corresponding technical solution depart from the scope of the technical solution of each embodiment of the present application.

What is claimed is:

1. A display panel, comprising
a display substrate, wherein each display pixel in the display substrate comprises a plurality of subpixel regions; and
an encapsulation layer, located on a light outlet side of the display substrate, and comprising a first inorganic layer and an organic layer which are successively arranged in a direction away from the display substrate, wherein the first inorganic layer comprises light transmitting regions and thickening regions, each light transmitting region correspondingly covers at least one subpixel region in an orthographic direction on the display substrate, and a thickness of each thickening region is greater than a thickness of the light transmitting region.

2. The display panel of claim 1, wherein the thickness of each thickening region is at least 1.2 times the thickness of the light transmitting region.

3. The display panel of claim 1, wherein the thickness of each thickening region is within 3 times the thickness of the light transmitting region.

4. The display panel of claim 1, wherein the thickness of each light transmitting region ranges from 0.5 μm to 1.5 μm.

5. The display panel of claim 1, wherein a width of each light transmitting region is greater than a width of the corresponding subpixel region in the orthographic direction of the light transmitting region.

6. The display panel of claim 1, wherein each display pixel comprises a first subpixel region, a second subpixel region and a third subpixel region, and correspondingly, each light transmitting region of the first inorganic layer comprises a first light transmitting region, a second light transmitting region and a third light transmitting region; the first light transmitting region correspondingly covers the first subpixel region in the orthographic direction, the second light transmitting region correspondingly covers the second subpixel region in the orthographic direction, and the third light transmitting region correspondingly covers the third subpixel region in the orthographic direction; and a thickness of the first light transmitting region is a first thickness, a thickness of the second light transmitting region is a second thickness, an a thickness of the third light transmitting region is a third thickness.

7. The display panel of claim 6, wherein the first thickness, the second thickness and the third thickness are all different.

8. The display panel of claim 6, wherein two of the first thickness, the second thickness and the third thickness are the same, and are not the same as the thickness of the third party.

9. The display panel of claim 6, wherein an overall thickness of the encapsulation layer is less than or equal to 20 μm, and the overall thickness of the encapsulation layer is equal to or greater than a thickness of the first inorganic layer.

10. The display panel of claim 1, wherein a width W of each light transmitting region is greater than a width L of the subpixel region, and meets a following condition: L<W≤L+5 μm.

11. The display panel of claim 1, wherein a material of the first inorganic layer is any one of SiOx, SiNx, SiNOx and ceramic.

12. A preparation method of a display panel, comprising:
forming a first inorganic layer on a light outlet side of a display substrate, wherein each display pixel in the display substrate comprises a plurality of subpixel regions;
forming a mask layer on a side of the first inorganic layer away from the display substrate;
performing perforating machining on a photoresist layer corresponding to a plurality of light transmitting regions on the first inorganic layer, to expose the plurality of light transmitting regions on the first inorganic layer, each light transmitting region correspondingly covering at least one subpixel region in an orthographic direction on the display substrate; and
etching each light transmitting region on the first inorganic layer, to etch the light transmitting region to a preset thickness.

13. The preparation method of the display panel of claim 12, further comprising: clearing away the mask layer, and forming other encapsulation layers on the side of the first inorganic layer away from the display substrate.

14. The preparation method of the display panel of claim 13, wherein the other encapsulation layers comprise an organic layer and a second inorganic layer, and the second inorganic layer is located on a side of the organic layer away from the first inorganic layer.

15. A display apparatus, comprising a display panel, wherein the display panel comprises:
a display substrate, wherein each display pixel in the display substrate comprises a plurality of subpixel regions; and
an encapsulation layer, located on a light outlet side of the display substrate, and comprising a first inorganic layer and an organic layer which are successively arranged in a direction away from the display substrate, wherein the first inorganic layer comprises light transmitting regions and thickening regions, each light transmitting region correspondingly covers at least one subpixel region in an orthographic direction on the display substrate, and a thickness of each thickening region is greater than that of the light transmitting region.

16. A display apparatus, comprising a display panel, wherein a preparation method of the display panel comprises:
forming a first inorganic layer on a light outlet side of a display substrate, wherein each display pixel in the display substrate comprises a plurality of subpixel regions;
forming a photoresist layer on a side of the first inorganic layer away from the display substrate;
performing exposure and development on the photoresist layer corresponding to a plurality of light transmitting regions on the first inorganic layer, to expose the plurality of light transmitting regions on the first inorganic layer, each light transmitting region correspondingly covering at least one subpixel region in an orthographic direction on the display substrate; and
etching each light transmitting region on the first inorganic layer, to etch each light transmitting region to a preset thickness, and forming thickening regions between the adjacent light transmitting regions.
